(19) United States
(12) Patent Application Publication
(10) Pub. No.: US 2017/0086292 A1
(43) Pub. Date: Mar. 23, 2017

(54) PREPREG AND METHOD OF MANUFACTURING THE SAME

(71) Applicant: SAMSUNG ELECTRO-MECHANICS CO., LTD., Suwon-si (KR)

(72) Inventors: Eun-Sil KIM, Hwaseong-si (KR); Keun-Yong LEE, Suwon-si (KR); Seong-Hyun YOO, Seongnam-si (KR); Sang-Hyun SHIN, Suwon-si (KR); Jin-Ho HONG, Suwon-si (KR)

(73) Assignee: SAMSUNG ELECTRO-MECHANICS CO., LTD., Suwon-si (KR)

(21) Appl. No.: 15/202,037

(22) Filed: Jul. 5, 2016

(30) Foreign Application Priority Data
Sep. 17, 2015 (KR) 10-2015-0131830

(51) Int. Cl. H05K 1/03; B32B 27/06; B32B 37/10; B32B 37/06; H05K 3/00; B32B 37/14

(52) U.S. Cl. CPC H05K 1/0306; H05K 1/0373; H05K 1/038; H05K 3/0011; B32B 37/14; B32B 37/10; B32B 37/06; B32B 27/06; H05K 2203/066; H05K 2203/068; B32B 2457/08

(57) ABSTRACT

A prepreg includes a core layer, a first resin layer including a first resin material and laminated on a first side of the core layer, the first resin material impregnating a portion of the core layer, and a second resin layer including a second resin material and laminated on a second side of the core layer, the second resin material impregnating a portion of the core layer so as to form a non-linear joint interface with the first resin material.

### CROSS-REFERENCE TO RELATED APPLICATIONS

This application claims the benefit under 35 USC 119(a) of Korean Patent Application No. 10-2015-0131830, filed on Sep. 17, 2015, in the Korean Intellectual Property Office, the entire disclosure of which is incorporated herein by reference for all purposes.

### BACKGROUND

1. Field

The following description relates to a prepreg and a method of manufacturing the same.

2. Description of Related Art

Printed circuit boards are installed in a variety of electronic devices. With the development of manufacturing technologies that produce smaller electronic devices, a demand exists for producing printed circuit boards that are also lighter, thinner and smaller. In a printed circuit board, wiring layers for forming circuit connections and insulating layers for forming interlayer insulation are alternately laminated. The wiring layers are mostly made of a metallic material such as, for example, copper, and the insulating layers are generally made of a polymer resin such as, for example, resin or epoxy.

In order to realize a thinner printed circuit board, the thickness of insulating layers would need to be reduced. However, when the thickness of insulating layers is reduced, it becomes difficult to control warpage characteristics of the printed circuit board. As a result, the electrical, thermal and mechanical properties of a printed circuit board may deteriorate because it is more difficult to control the thermal expansion, glass transition temperature and modulus of insulating layers in comparison to that of wiring layers. Wiring layers are made of a metallic material that generally exhibits a lower coefficient of thermal expansion, a higher glass transition temperature and a higher modulus in comparison to the dielectric materials used for forming insulating layers.

Moreover, there is a trend for installing an increased number of electronic components in a printed circuit board. Thus, multiple insulating layers may be laminated in a printed circuit board in order to design various wiring schemes, requiring a high functional prepreg to secure electrical insulation between adjacent wires while forming fine wiring patterns. A prepreg is described in Japan Patent No. 2012-054323.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a prepreg includes a core layer, a first resin layer including a first resin material and laminated on a first side of the core layer, the first resin material impregnating a portion of the core layer, and a second resin layer including a second resin material and laminated on a second side of the core layer, the second resin material impregnating a portion of the core layer so as to form a non-linear joint interface with the first resin material, the second resin material having a different viscosity from that of the first resin material.

The core layer may include fabric cloth or glass cloth having fabric or glass filaments woven therein.

The first resin layer and the second resin layer each may include inorganic filler.

A content of the inorganic filler in the first resin layer may be different from a content of the inorganic filler in the second resin layer.

The contents of the inorganic filler in the first resin layer and the second resin layer may be each 80 wt % or less.

A thickness of the first resin layer may be different from a thickness of the second resin layer.

In another general aspect, a method of manufacturing a prepreg involves laminating a first resin layer on a first side of a core layer and a second resin layer on a second side of the core layer, the core layer including fabric cloth or glass cloth, and the second resin layer having a viscosity different from that of the first resin layer; and applying thermal compression to the core layer, the first resin layer and the second resin layer such that a material forming the first resin layer and a material forming the second resin layer are impregnated into portions of the core layer as to form a non-linear joint interface.

The laminating of the first resin layer and the second resin layer may involve applying the first resin layer and the second resin layer on respective cover films and maintaining the first resin material and the second resin material in a semi-hardened state.

The applying of thermal compression may involve laminating a pair of copper layers, respectively, on an outer surface of the first resin layer and the second resin layer; applying thermal compression on either surface of the copper layers; and removing the copper layers.

Other features and aspects will be apparent from the following detailed description, the drawings, and the claims.

### BRIEF DESCRIPTION OF DRAWINGS

FIG. 1 is a cross-sectional view illustrating an example of a prepreg.

FIG. 2 is a cross-sectional view illustrating another example of a prepreg.

FIGS. 3 through 6 are cross-sectional views illustrating an example of a method of manufacturing a prepreg.

FIG. 7 is a cross-sectional view illustrating another example of a prepreg.

FIG. 8 is a photograph illustrating an example of a prepreg.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

Hereinafter, certain embodiments of the present disclosure will be described in detail with reference to the accompanying drawings.

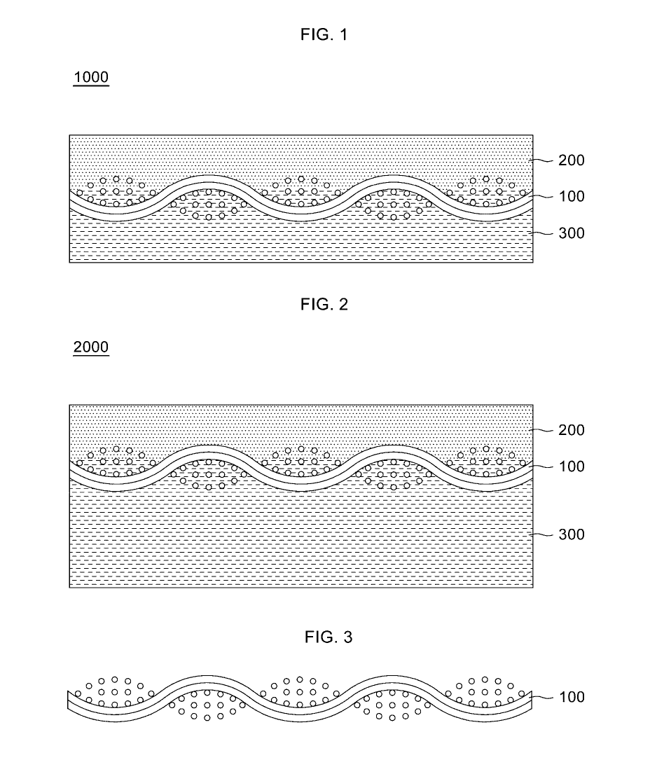

FIG. 1 illustrates an example of a prepreg.

Referring to FIG. 1, a prepreg 1000 includes a core layer 100, a first resin layer 200 and a second resin layer 300.

The core layer 100 is a member having the materials of first and second resin layers 200, 300 impregnated therein through, for example, an impregnation process so as to minimize warpage in the prepreg 1000 and lower a coefficient of thermal expansion (CTE).

The core layer 100, which may be made of fabric cloth or glass cloth, has a woven structure in which 1 to 3 rows of fabric or glass filaments are crossed with each other and thus has a higher modulus than the resin materials 200, 300. Accordingly, when heat and pressure are applied while the resin materials 200, 300 are laminated, the occurrence of warpage in the prepreg 1000 may be minimized.

The core layer 100 has protruding portions formed therein according to an arrangement of the woven fabric or glass filaments at locations where the fabric or glass filaments overlap in a crisscross pattern. A height of the protruding portions may vary according to the number and arrangement of the fabric or glass filaments forming the core layer 100, and may be generally greater if bundles having a greater number of filaments are used. That is, at an overlapping location of the bundles of fabric or glass filaments, the fabric or glass filaments bulge out, and the rest of the locations of the core layer 100 are relatively concaved in with respect to the protruding portions.

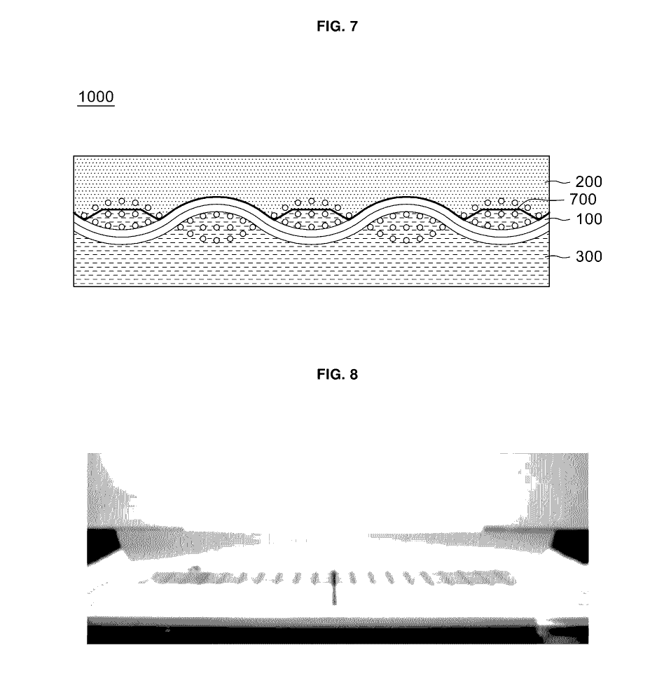

Because the core layer 100 include portions of the resin materials that form the first and second resin layers 200, 300 which are impregnated therein, a variation in contents of resin composition and inorganic filler constituting the resin materials would cause a difference in fluidity of the resin composition within the core material 100. Thus, a depth of penetration is varied at a location of the core material 100 having a high density due to the fluidity of the resin composition, thereby forming a non-linear joint interface within the core material 100. An example of a non-linear joint interface 700 is illustrated in FIG. 7. Referring to FIG. 7, the fluidity of the resin composition forming the first resin layer 200 is lower than the fluidity of the resin composition forming the second resin layer 300. However, the possible location of the boundary of the non-linear join interface is not limited to this example.

The first resin layer 200 is a member laminated on one side of the core material 100 and having a portion of its material impregnating a portion of the core layer 100 so as to have the non-linear joint interface. The first resin layer 200 may be made of an organic material such as, for example, epoxy or resin. However, the material for forming the first resin layer 200 is not restricted to organic materials such as epoxy or resin, and any thermosetting resin or ultraviolet (UV) curing resin may be used to form the first resin layer 200 as long as it is an organic material that is capable of impregnating the spaces between the fabric or glass filaments that form the core layer 100.

As an example of a thermalsetting resin, a urea resin, melamine resin, bismaleimide resin, polyurethane resin, benzoxazine resin, cyanate ester resin, bisphenol-S epoxy resin, bisphenol-F epoxy resin or copolymer epoxy resin of bisphenol-S and bisphenol-F and the like may be used. However, the disclosure is not limited to the thermosetting resin described herein, and the first resin layer 200 may be formed with any known resin as long as it has a thermosetting property.

According to one example, an acrylic resin may be used as a UV curing resin, but the disclosure is not limited to the UV curing resin described herein. The resin material may be implemented with any known resin having a UV curing property.

The second resin layer 300 may have a different minimum viscosity from the first resin material 200. The second resin layer 300 is a member laminated on the other side of the core layer 100, and a material forming the second resin layer penetrates into the core layer 100 so as to impregnate a portion thereof, forming a non-linear joint interface with the material that forms the first resin layer 200. The second resin layer 300 may be made of an organic material such as, for example, epoxy or resin. However, the material for forming the second resin layer 300 is not restricted to an organic material such as epoxy or resin, and any thermosetting resin or UV curing resin may be introduced to the second resin material 300 as long as it is an organic material that is capable of impregnating the spaces between the fabric or glass filaments of the core layer 100.

In this example, because the material forming the second resin layer 300 has a different minimum viscosity from the material forming the first resin layer 200, the level by which the first resin material penetrates the core layer 100 is different from the level by which the second resin material penetrates the core material 100, as illustrated in FIG. 1.

That is, in the event that the viscosity of a resin material forming the first resin layer 200 or the second resin layer 300 were relatively high, a smaller content of resin composition would move into the core layer 100 for a given time under a given pressure, and it would be hard for the resin composition to penetrate into densely-woven portions of the core layer 100, but it would easily penetrate into loosely-woven portions of the core layer 100. Accordingly, a non-linear joint interface 700 is formed inside the core layer 100, the prepreg 1000 may be formed in an asymmetric geometry about the core layer 100.

Therefore, the warpage may be reduced and high peel strength and durability be realized through the non-linear joint interface. Further, warpage may be induced in opposite directions through the asymmetric structure of the resin materials 200, 300 about the core material 100, thereby making it possible to control an overall warpage direction of the prepreg 1000.

In the prepreg 1000 in accordance with FIG. 1, the first resin layer 200 and the second resin layer 300 may contain inorganic filler. The prepreg 1000 may be vulnerable to thermal deformation because the prepreg 1000 will have a higher coefficient of thermal expansion if the first resin layer 200 and the second resin layer 300 are made of a thermosetting or UV curing resin only. By having the inorganic filler included in the resin layers 200, 300, the coefficient of thermal expansion may be lowered and the warpage deformation may be minimized when thermal compression is applied.

In this example, the content of inorganic filler may be different in the first resin layer 200 and in the second resin layer 300. In other words, the first resin layer 200 and the second resin layer 300 may be made of a same resin composition but may have different contents of inorganic filler to give different viscosities from each other.

The contents of inorganic filler in the first resin layer 200 and the second resin layer may be, for example, 80 wt % or less. In another example, the contents of inorganic filler in the first resin layer 200 and the second resin layer may be, for example, 75 wt % or less. In general, if the viscosity of the resin materials 200, 300 is 2×10⁴ Pas or higher, the resin composition is not fluid and thus is not impregnated into the core layer 100, thereby forming an independent resin layer. According to this example, the content of inorganic filler, when the resin composition stops flowing, is approximately 80 wt %.

Therefore, in the prepreg 1000 according to one example, the content of inorganic filler is restricted to 80 wt % or less in the resin materials 200, 300 to induce impregnation of the resin materials that form the first and second resin layers 200, 300 into the core material 100.

FIG. 2 illustrates another example of a prepreg.

Referring to FIG. 2, a prepreg 2000 includes a first resin layer 200 and a second resin layer 300, and the first and second resin layers 200, 300 have different thicknesses from each other. By configuring the first resin layer 200 and the second resin layer 300 to have different viscosities and different thicknesses from each other, it is possible to control an overall direction of warpage of the prepreg 2000 in various ways.

Accordingly, it is possible to utilize a prepreg 2000 configured in accordance with this example in various structures of printed circuit board depending on the requirement. FIG. 8 illustrates a photograph of a prepreg 2000.

Other than the above-described technical features, the prepreg 2000 has the same or similar elements as those of the prepreg 1000 illustrated in and described with reference to FIG. 1, and thus these same or similar elements will not be redundantly described herein.

FIGS. 3 through 6 illustrate an example of a method of manufacturing a prepreg. In this example, the thicknesses of the first and second resin layers 200, 300 are the same. Meanwhile, to obtain the example of the prepreg illustrated in FIG. 2, the method illustrated in FIGS. 3 through 6 may be performed with different thicknesses for the first and second resin layers 200, 300. The processes used for the method of manufacturing the prepreg 2000 is otherwise similar to that illustrated in FIGS. 3 through 6.

Referring to FIGS. 3 through 6, the method of manufacturing a prepreg starts with preparing a core layer 100 constituted with fabric cloth or glass cloth (see FIG. 3). As described above, the core layer 100 is a woven object having protruding portions, and may be formed by overlapping fabric or glass filaments on an upper surface and a lower surface thereof.

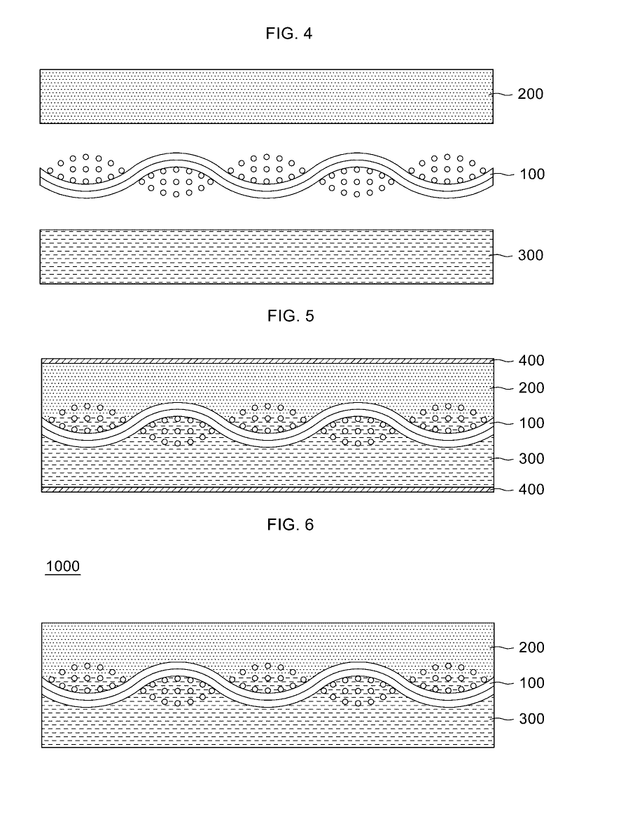

Next, a first resin layer 200 is laminated on one surface of the core layer 100, and a second resin layer 300, having a different viscosity from that of the first resin layer 200, is laminated on the other surfaced of the core layer 100, thereby forming a resin laminate (see FIG. 4). The resin layers 200, 300 have a predetermined thickness of resin coated on a cover film, which is an insulation film or a copper foil, and may be coated in a B-stage semi-hardened state.

Then, heat and pressure are applied to the resin laminate so as to allow portions of the materials forming the first resin layer 200 and the second resin layer 300 to be impregnated into the core layer 100 and to allow a non-linear joint interface to be formed (see FIGS. 5 and 6). The resin laminate may be pressed using a pressing method such as V-press, V-press lamination or roll-press, and a predetermined amount of heat may be applied while the resin laminate is pressed.

When the resin layers 200, 300 are tightly adhered to the core layer 100 by thermal compression, surfaces of the resin layers 200, 300 joining the core layer 100 have a phase change and are integrally coupled with the core layer 100, and joint interfaces of the resin layers 200, 300 form the non-linear joint interfaces along the protruding portions of the core layer 100.

The non-linear joint interfaces of the resin layers 200, 300 may increase a surface area of joint between the laminated resin layers 200, 300. Accordingly, when the core layer 100 is viewed from above, the bent portions forming a number of protrusions are inserted into and joined with the resin layers 200, 300, thereby preventing gaps or exfoliation in the prepreg.

Meanwhile, the process of thermal compression may include laminating a copper layer 400, such as, for example, a cover film made of a copper foil, on outer surfaces of the first resin layer 200 (see FIG. 5) and the second resin layer 300, respectively, and applying thermal compression either surface of the copper layers 400 (see FIG. 6).

That is, by applying thermal compression and hardening the copper layers 400, which are for use as cover films, in order to apply thermal compress the semi-hardened state of resin layers 200, 300, and then removing the copper layers 400 through, for example, etching, a prepreg 1000 constituted with the core layer 100 and the resin layers 200, 300 only may be readily manufactured.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A prepreg comprising:
a core layer;
a first resin layer comprising a first resin material and laminated on a first side of the core layer, the first resin material impregnating a portion of the core layer; and
a second resin layer comprising a second resin material and laminated on a second side of the core layer, the second resin material impregnating a portion of the core layer so as to form a non-linear joint interface with the first resin material, the second resin material having a different viscosity from that of the first resin material.

2. The prepreg of claim 1, wherein the core layer comprises fabric cloth or glass cloth having fabric or glass filaments woven therein.

3. The prepreg of claim 2, wherein the first resin layer and the second resin layer each comprise inorganic filler.

4. The prepreg of claim 3, wherein a content of the inorganic filler in the first resin layer is different from a content of the inorganic filler in the second resin layer.

5. The prepreg of claim 4, wherein the contents of the inorganic filler in the first resin layer and the second resin layer are each 80 wt % or less.

6. The prepreg of claim 1, wherein a thickness of the first resin layer is different from a thickness of the second resin layer.

7. A method of manufacturing a prepreg, comprising:
laminating a first resin layer on a first side of a core layer and a second resin layer on a second side of the core layer, the core layer comprising fabric cloth or glass cloth, and the second resin layer having a viscosity different from that of the first resin layer; and
applying thermal compression to the core layer, the first resin layer and the second resin layer such that a material forming the first resin layer and a material forming the second resin layer are impregnated into portions of the core layer as to form a non-linear joint interface.

8. The method as set forth in claim 7, wherein the laminating of the first resin layer and the second resin layer comprises applying the first resin layer and the second resin layer on respective cover films and maintaining the first resin material and the second resin material in a semi-hardened state.

9. The method as set forth in claim 7, wherein the applying of thermal compression comprises:
laminating a pair of copper layers, respectively, on an outer surface of the first resin layer and the second resin layer;
applying thermal compression on either surface of the copper layers; and
removing the copper layers.
